(19) United States
(12) Patent Application Publication
(10) Pub. No.: US 2014/0093638 A1
(43) Pub. Date: Apr. 3, 2014

(54) METHOD OF DISPENSING MATERIAL BASED ON ANGULAR LOCATE FEATURE

(71) Applicants: Jonathan Joel Bloom, North Falmouth, MA (US); Michael E. Donelan, Upton, MA (US)

(72) Inventors: Jonathan Joel Bloom, North Falmouth, MA (US); Michael E. Donelan, Upton, MA (US)

(21) Appl. No.: 13/630,259

(22) Filed: Sep. 28, 2012

(51) Int. Cl. H05K 3/00

(52) U.S. Cl. CPC H05K 3/00
USPC 427/58; 118/713

(57) ABSTRACT

A dispensing system includes a frame, a dispensing unit gantry movably coupled to the frame, and a dispensing unit coupled to the dispensing unit gantry. The dispensing unit further includes a vision system gantry coupled to the frame and a vision system coupled to the vision system gantry. A controller is coupled to the dispensing unit gantry, the dispensing unit, the vision system gantry, and the vision system. The controller is configured to obtain an image of a fiducial provided on the electronic substrate, obtain an image of at least a portion of an object positioned on the electronic substrate, orient the object with respect to the dispensing unit, and perform a dispense operation to secure the object to the electronic substrate. Methods of dispensing material on a substrate are further disclosed.

### BACKGROUND OF THE DISCLOSURE

1. Field of the Disclosure

This disclosure relates generally to apparatus and methods for dispensing a viscous material on a substrate, such as a printed circuit board, and more particularly to a system and related methods for accurately dispensing material based on locating an angular feature on the circuit board.

2. Discussion of Related Art

There are several types of prior art dispensing systems used for dispensing precise amounts of liquid or paste for a variety of applications. One such application is the assembly of integrated circuit chips and other electronic components onto circuit board substrates. In this application, automated dispensing systems are used for dispensing very small amounts, or dots, of viscous material onto a circuit board. The viscous material may include liquid epoxy or solder paste, or some other related material. Prior to performing a dispensing operation, the circuit board must be aligned or otherwise registered with a dispenser of the dispensing system. In one known method, this may be achieved by employing a vision system of the dispensing system to verify the location of landmarks, otherwise known as fiducials, on the circuit board. Specifically, to align the circuit board with the dispensing unit of the dispensing system, images of at least two fiducials are taken by a camera of the vision system. If the circuit board is out of position, a gantry capable of moving the dispenser may be manipulated to account for the actual position of the circuit board. In another embodiment, a support surface upon which the circuit board rests may be manipulated to accurately position the circuit board prior to performing a dispense operation.

One issue associated with the use of identifying fiducials to align the circuit board with the dispensing unit is when the area requiring dispensing is not well defined with reference to the fiducials. For example, if the area to dispense is not referenced with respect to the fiducials, the resulting dispense operation may be very inaccurate, and under many instances, may not meet the processing requirements.

### SUMMARY OF THE DISCLOSURE

The present disclosure describes a technique of dispensing material onto substrates having areas that are not well defined by locating one or more angular features on the substrate (as well as one or more fiducials) and dispensing material based on the angular feature(s).

This technique includes using a single fiducial to determine the location and orientation of an object to be dispensed on and using this information to orient a dispensing unit relative to the found object to enhance the ability to accurately dispense a line of material or one or more dots of material located on a substrate, such as a circuit board. To dispense a line accurately on a substrate, an object (e.g., a component mounted on a circuit board or the like) is located on the circuit board and the location, orientation and angle of the object is determined to dispense a line relative to the object. While the dispensed line is frequently perpendicular or parallel to the found orientation of the object, the dispensed line is not required to be perpendicular or parallel. The dispensed line may be straight or in the form of an arc. The dispensed line may be contiguous or in the form of one or more dots or line segments. Line patterns and sub-patterns may be utilized as well. When dispensing, sensing a z-axis height above the circuit board may be used. To enhance the accuracy of the dispense operation, a subset of features of the object may be selected.

One aspect of the present disclosure is directed to a dispensing system for depositing material on an electronic substrate. In one embodiment, the dispensing system includes a frame, a dispensing unit gantry movably coupled to the frame, and a dispensing unit coupled to the dispensing unit gantry. The dispensing unit is configured to deposit material onto the substrate during the dispense operation. The dispensing unit further includes a vision system gantry coupled to the frame and a vision system coupled to the vision system gantry. The vision system is configured to obtain one or more images of the electronic substrate prior to performing the dispense operation. A controller is coupled to the dispensing unit gantry, the dispensing unit, the vision system gantry, and the vision system. The controller is configured to obtain an image of a fiducial provided on the electronic substrate, obtain an image of at least a portion of an object positioned on the electronic substrate, orient the object with respect to the dispensing unit, and perform a dispense operation to secure the object to the electronic substrate.

Embodiments of the dispensing system further may include a support assembly coupled to the frame. The support assembly may be configured to support the electronic substrate during a dispense operation. The controller further may be configured to manipulate the vision system with the vision gantry system to move to a position defined by a feature of the object and to acquire the image. Performing a dispense operation may include dispensing material in the shape of an arc. The object may be a camera having a body and a plurality of tabs extending from a periphery of the body. The dispensing unit may be configured to dispense material between adjacent tabs. The controller further may be configured to dispense lines of material and/or dots of material. The dispensing unit may include a sensor configured to sense a z-axis height on the electronic substrate.

Another aspect of the disclosure is directed to a method of depositing material on an electronic substrate with a dispensing system of the type including a frame, a dispensing unit gantry movably coupled to the frame, a dispensing unit coupled to the dispensing unit gantry, the dispensing unit being configured to deposit material onto the substrate during the dispense operation, a vision system gantry coupled to the frame, and a vision system coupled to the vision system gantry, the vision system being configured to obtain one or more images of the electronic substrate prior to performing the dispense operation. In one embodiment, the method comprises: obtaining an image of a fiducial provided on the electronic substrate; obtaining an image of at least a portion of an object positioned on the electronic substrate; orienting the object with respect to the dispensing unit; and performing a dispense operation to secure the object to the electronic substrate.

Embodiments of the method further may include sensing a z-axis height on the electronic substrate and/or supporting the electronic substrate during a dispense operation with a support assembly coupled to the frame. The method may be performed under the control of a controller configured to manipulate the vision system with the vision gantry system to move to a position defined by a feature of the object and to acquire the image. The controller further may be configured to dispense lines of material and/or dots of material. Performing a dispense operation may include dispensing material in the shape of an arc. The object may be a camera having a body and a plurality of tabs extending from a periphery of the body. The dispensing unit may be configured to dispense material between adjacent tabs.

### BRIEF DESCRIPTION OF THE DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a schematic view of a dispenser of an embodiment of the present disclosure;

FIG. 2 is a schematic block diagram of a method of dispensing material based on the angular location of a feature;

FIG. 3 is a top plan view of an exemplary object provided on a substrate, such as a printed circuit board;

FIGS. 4-8 are screen shots of exemplary user interfaces used to perform an angular locate command of a method of the present disclosure; and

FIG. 9 is an image of a sample showing found angular locate features.

### DETAILED DESCRIPTION OF THE DISCLOSURE

For the purposes of illustration only, and not to limit the generality, the present disclosure will now be described in detail with reference to the accompanying figures. This disclosure is not limited in its application to the details of construction and the arrangement of components set forth in the following description or illustrated in the drawings. The principles set forth in this disclosure are capable of other embodiments and of being practiced or carried out in various ways. Also the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

Various embodiments of the present disclosure are directed to viscous material dispensing systems, devices including dispensing systems, and methods of locating objects on electronic substrates, such as printed circuit boards, and performing dispensing operations on the substrates. Embodiments disclosed herein are directed to techniques for dispensing material on an electronic substrate by using a single fiducial and by locating and orienting an object, and using the location of the object to orient a dispensing unit or pump of the dispensing system to enhance a dispense operation.

The systems and methods disclosed herein may frequently perform a dispense operation that is perpendicular or parallel to the found orientation of the object; however, this is not a requirement. The dispensed line may be straight or in the form of an arc.

The systems and methods further enable the accurate dispense of dots or line segments. Specifically, a dispensing unit of the dispensing system may be modified to dispense dots.

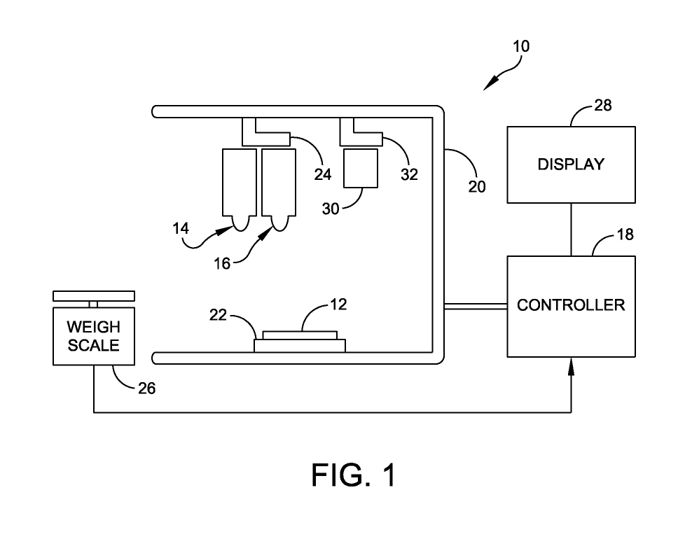

FIG. 1 schematically illustrates a dispenser, generally indicated at 10, according to one embodiment of the present disclosure. The dispenser 10 is used to dispense a viscous material (e.g., an adhesive, encapsulant, epoxy, solder paste, underfill material, etc.) or a semi-viscous material (e.g., soldering flux, etc.) onto an electronic substrate 12, such as a printed circuit board or semiconductor wafer. The dispenser 10 may alternatively be used in other applications, such as for applying automotive gasketing material or in certain medical applications. It should be understood that references to viscous or semi-viscous materials, as used herein, are exemplary and intended to be non-limiting. The dispenser 10 includes first and second dispensing units or heads, generally indicated at 14 and 16, respectively, and a controller 18 to control the operation of the dispenser. Although two dispensing units are shown, it should be understood that one or more dispensing units may be provided.

The dispenser 10 may also include a frame 20 having a base or support 22 for supporting the substrate 12, a dispensing unit gantry 24 movably coupled to the frame 20 for supporting and moving the dispensing units 14, 16, and a weight measurement device or weigh scale 26 for weighing dispensed quantities of the viscous material, for example, as part of a calibration procedure, and providing weight data to the controller 18. A conveyor system (not shown) or other transfer mechanism, such as a walking beam may be used in the dispenser 10 to control loading and unloading of substrates to and from the dispenser. The gantry 24 can be moved using motors under the control of the controller 18 to position the dispensing units 14, 16 at predetermined locations over the substrate. The dispenser 10 may include a display unit 28 connected to the controller 18 for displaying various information to an operator. There may be an optional second controller for controlling the dispensing units. Also, each dispensing unit 14, 16 can be configured with a z-axis sensor to detect a height at which the dispensing unit is disposed above the electronic substrate 12 or above a feature mounted on the electronic substrate. The z-axis sensor is coupled to the controller 18 to relay information obtained by the sensor to the controller.

Prior to performing a dispensing operation, as described above, the substrate, e.g., printed circuit board, must be aligned or otherwise in registration with a dispenser of the dispensing system. The dispenser further includes a vision system 30, which is coupled to a vision system gantry 32 movably coupled to the frame 20 for supporting and moving the vision system. As described, the vision system 30 is employed to verify the location of landmarks, known as fiducials, on the substrate. Once located, the controller can be programmed to manipulate the movement of one or both of the dispensing units 14, 16 to dispense material on the electronic substrate.

Systems and methods of the present disclosure are directed to dispensing material onto a substrate, e.g., a circuit board, by locating an object provided on the substrate with both location and angular components. The description of the systems and methods provided herein reference exemplary electronic substrates 12 (e.g., printed circuit boards), which are supported on the support 22 of the dispenser 10. In one embodiment, the dispense operation is controlled by the controller 18, which may include a computer system configured to control material dispensers. In another embodiment, the controller 18 may be manipulated by an operator. The controller 18 is configured to manipulate the movement of the vision system gantry 32 to move the vision system so as to obtain one or more images of the electronic substrate 12. The controller 18 further is configured to manipulate the movement of the dispensing unit gantry 24 to move the dispensing units 14, 16 to perform dispensing operations.

The angular locate feature of the systems and methods of the present disclosure uses the known geometry of a special object, which provides x-axis, y-axis and theta information derived from its relative position with respect to one or more fiducials provided on the electronic substrate. In one embodiment, the special object may be an item that is mounted on the substrate, such as a mega pixel camera. Such a camera typically includes features that are difficult to orient with respect to the electronic substrate and the dispenser. Specifically, one issue associated with the use of such cameras is the difficulty of aligning the camera and the electronic substrate with the dispensing unit is when the area requiring dispensing is not well defined with reference to the camera. For example, if the area to dispense is not referenced with respect to the camera, the resulting dispense operation may be very inaccurate, and under many instances, may not meet the processing requirements.

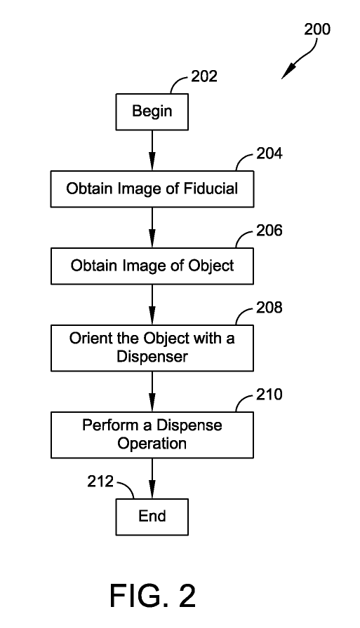

In one embodiment, an exemplary method is illustrated in FIG. 2. As shown, the method of dispensing material based on locating angular features of an object is generally indicated at 200.

As shown, the method begins at 202. At 204, the vision system is employed to obtain an image of at least one known fiducial. In most applications fiducials are located in known locations on the substrate or carrier, such as the corners of the electronic substrate, and two fiducials are located. The location of the fiducial is stored by the controller of the dispenser.

At 206, the vision system is further employed to obtain an image or images of the object. In a certain embodiment, the object is a camera having features, such as tabs. In some embodiments, the camera may be inserted into a feature mounted on the electronic substrate, such as a circular barrel or rim. When inserted, the orientation of the features with respect to the electronic substrate is unknown. As with the fiducial, the location of the object is stored by the controller of the dispenser.

At 208, the controller determines the orientation of the object based on the location of the features of the object with respect to the known location of the fiducial of the electronic substrate and the position of the dispensing unit of the dispenser. With the orientation of the object known, the areas requiring dispensing, e.g., the areas between the features of the object, can be determined.

At 210, a dispense operation is performed. In one embodiment, material, such as epoxy, is dispensed between the tabs of the camera in a slot between the camera and an inner wall of the barrel. The dispense operation is performed under the control of the controller.

At 212, once the dispense operation completes dispensing material the method ends.

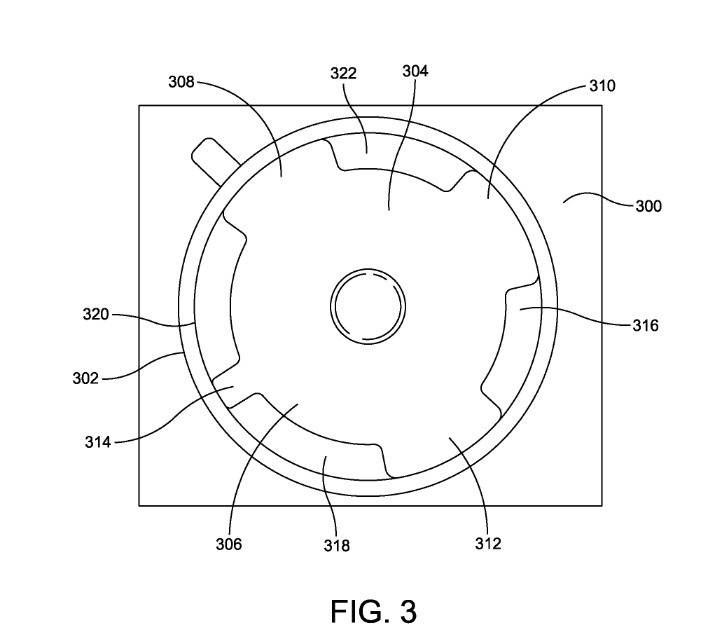

FIG. 3 illustrates an image of a portion of an electronic substrate 300. As shown, a support 302 is mounted on the electronic substrate 300 by any suitable method. In one embodiment, the support 302 is a circular barrel or rim, which is configured to receive an object 304, such as a mega pixel camera, so that the object is mounted within the support. As shown, the camera 304 includes a circular body 306, three larger tabs 308, 310, 312 and one smaller tab 314, each of the tabs extending beyond a periphery of the body. The arrangement is such that the camera 304 is inserted into the barrel 302 and secured to the electronic substrate 300 by a suitable adhesive, such as adhesive or epoxy.

When inserted, the camera 304 is not oriented with respect to the barrel 302 and the electronic substrate 300. Thus, the tabs 308, 310, 312, 314 of the camera 304 are oriented randomly with respect to the barrel 302 and the board 300. When securing the camera 304 to the electronic substrate 300, assembly material (e.g., adhesive) is dispensed within slots 316, 318, 320, 322 defined between an outer surface of the body 306 of the camera 302, the tabs 308, 310, 312, 314 of the camera and an inner surface of the barrel. The system and method of the present disclosure is designed to enable the dispensing unit of the dispenser to dispense material within the slots, which are randomly oriented with respect to the barrel 302 and the electronic substrate 300.

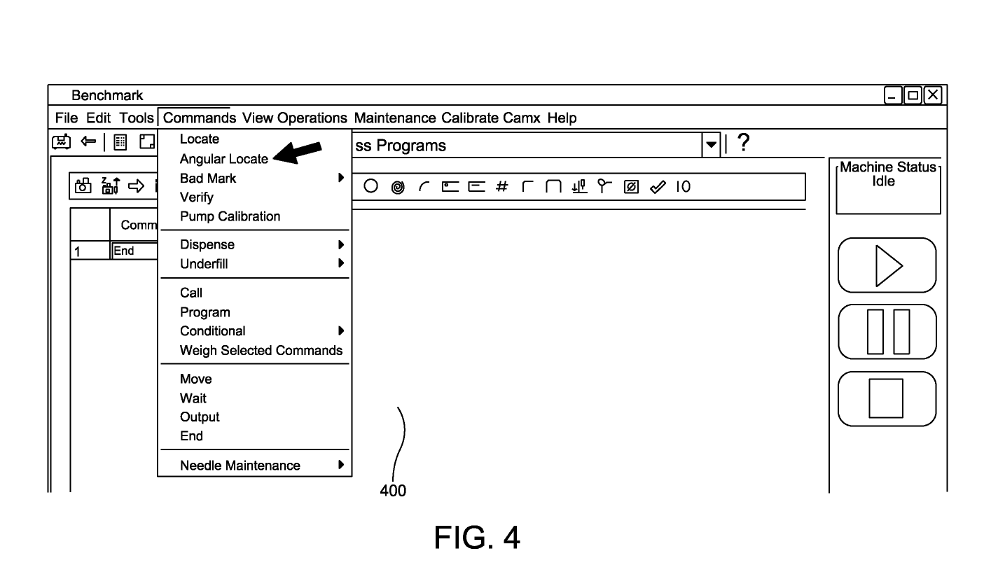

FIGS. 4-8 are screen shots of exemplary user interfaces used to perform an angular locate command of a method of the present disclosure. As shown, with reference to FIG. 4, a graphical user interface 400 is provided include an angular locate feature. A sub-program may be established to teach the angular locate fiducial and associate arcs, which can be called by the main program. From the commands menu, the angular locate command is selected.

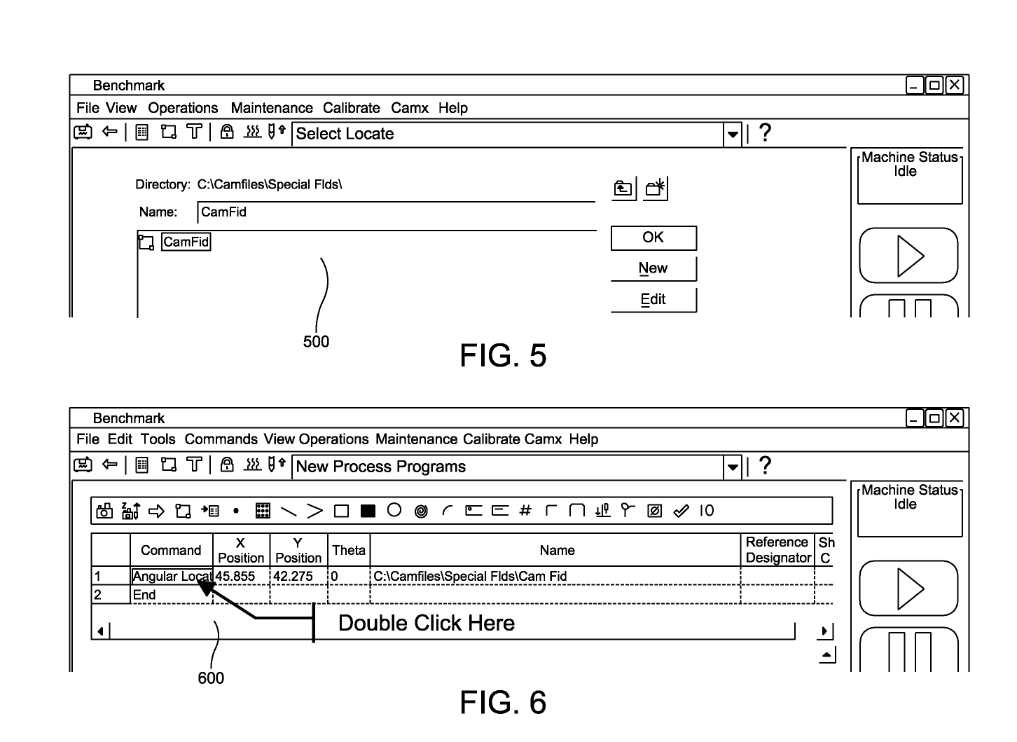

Referring to FIG. 5, when prompted to select a fiducial on graphical user interface 500, the operator or the controller navigates to a predetermined file (e.g., C:\CamFiles\SpecialFids), and selects the CamFid command. The operator or the controller then jogs the gantry to center the vision system in the center of the object (e.g., the camera) by using the cross-hairs on the display.

Referring to FIG. 6, with reference to graphical user interface 600, by double clicking the angular locate command, the operator or the controller selects the command grid.

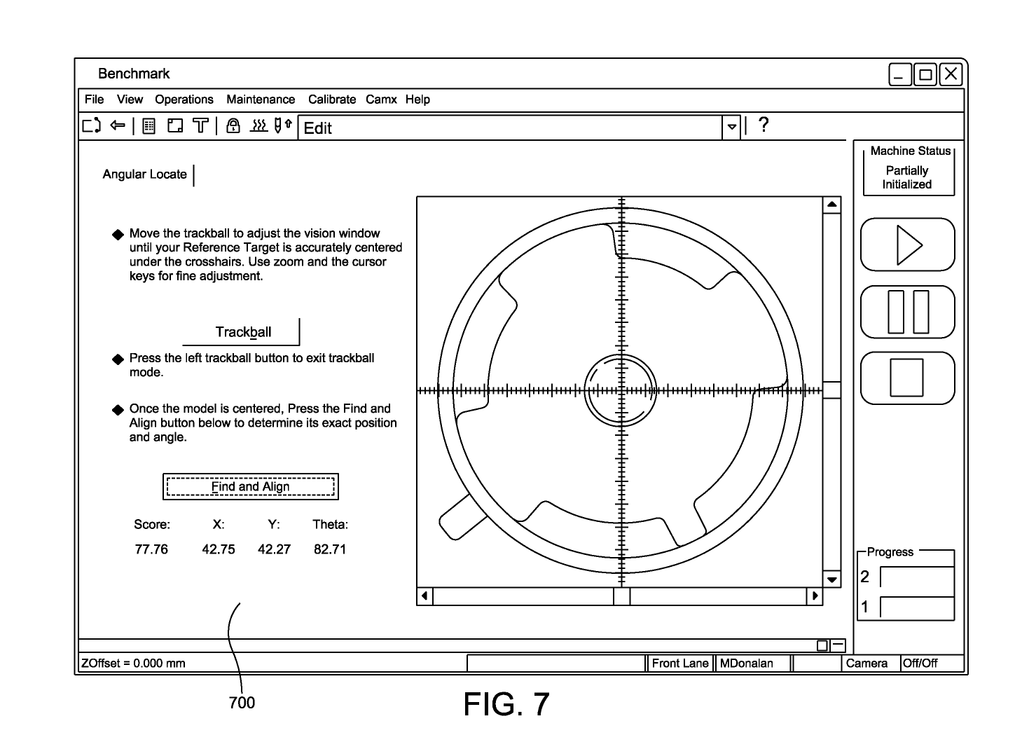

Referring to FIG. 7, with reference to graphical user interface 700, the operator or the controller next clicks a find and align button on the angular locate screen. This action determines the reference x-axis, y-axis and theta angle of the model. By pressing the find and align button, the operator or the controller fills these reference points in the interface. In certain embodiments, it should be noted that the search scores for these special models typically range in the seventies. When using an interactive mode, the operator then selects and presses “OK.”

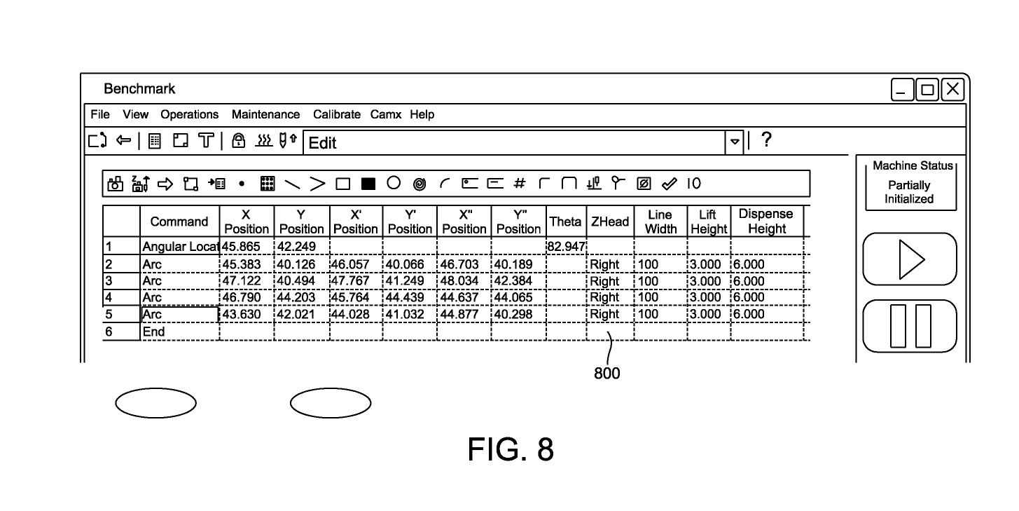

Referring to FIG. 8, with reference to graphical user interface 800, it should be noted that when the angular locate dialog is completed, the theta field of the command grid is filled in with the position locations of the arc. The operator or the controller then proceeds to add the arc commands.

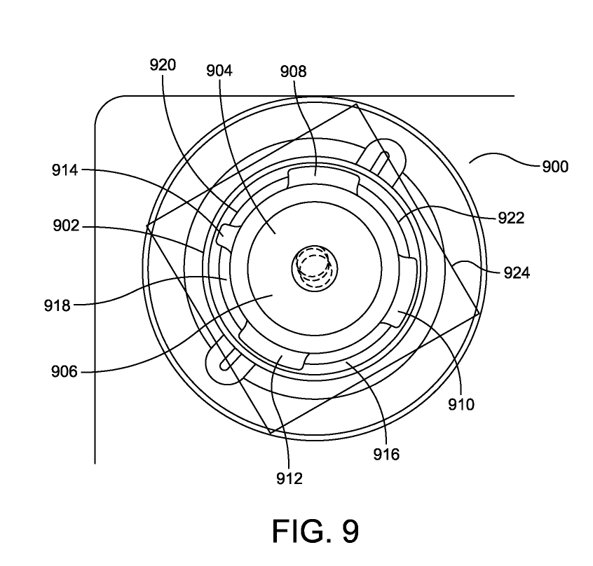

Referring to FIG. 9, once oriented, a box is displayed over an object to represent an accurate orientation of the object 904 with respect to the substrate 900 and the dispensing unit of the dispenser. Box 924 represents the proper orientation of the object 904 with respect to the support 902 and the electronic substrate 900. Once properly oriented, a dispense operation can take place in which material is dispensed in the spaces 916, 918, 920, 922 between adjacent tabs 908, 910, 912, 914 of the object 904, e.g., the camera. Any other object that has a random orientation relative to the substrate will be a candidate for performing the methods disclosed herein. For example, chips, covers, small switches, and other devices that are subassemblies in a carrier (e.g., 100 plus units) may be oriented and dispensed upon by using the methods disclosed herein.

The computer system may include an operating system that manages at least a portion of the hardware elements included in the computer system. Usually, a processor or controller executes an operating system which may be, for example, a Windows-based operating system, such as, Windows NT, Windows 2000 (Windows ME), Windows XP or Windows Vista operating systems, available from the Microsoft Corporation, a MAC OS System X operating system available from Apple Computer, one of many Linux-based operating system distributions, for example, the Enterprise Linux operating system available from Red Hat Inc., a Solaris operating system available from Sun Microsystems, or a UNIX operating system available from various sources. Many other operating systems may be used, and the embodiments disclosed herein are not intended to be limited to any particular implementation.

The processor and operating system together define a computer platform for which application programs in high level programming languages may be written. These component applications may be executable, intermediate, for example, C-, bytecode or interpreted code which communicates over a communication network, for example, the Internet, using a communication protocol, for example, TCP/IP. Similarly, aspects in accord with the present disclosure may be implemented using an object-oriented programming language, such as .Net, SmallTalk, Java, C++, Ada, or C# (C-Sharp). Other object-oriented programming languages may also be used. Alternatively, functional, scripting, or logical programming languages may be used.

Additionally, various aspects and functions in accordance with the present disclosure may be implemented in a non-programmed environment, for example, documents created in HTML, XML or other format that, when viewed in a window of a browser program, render aspects of a graphical-user interface or perform other functions. Further, various embodiments in accord with the present disclosure may be implemented as programmed or non-programmed elements, or any combination thereof. For example, a web page may be implemented using HTML while a data object called from within the web page may be written in C++. Thus, the disclosure is not limited to a specific programming language and any suitable programming language could also be used.

It should be noted that systems and methods described herein may be performed on objects other than mega pixel cameras. For example, the method may be performed on any type of electronic component mounted on an electronic substrate. The geometry of the object should be known prior to performing the method.

Having thus described several aspects of at least one embodiment of this disclosure, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A dispensing system for depositing material on an electronic substrate, the dispensing system comprising:
a frame;
a dispensing unit gantry movably coupled to the frame;
a dispensing unit coupled to the dispensing unit gantry, the dispensing unit being configured to deposit material onto the substrate during the dispense operation;
a vision system gantry coupled to the frame;
a vision system coupled to the vision system gantry, the vision system being configured to obtain one or more images of the electronic substrate prior to performing the dispense operation; and
a controller coupled to the dispensing unit gantry, the dispensing unit, the vision system gantry, and the vision system, the controller being configured to
obtain an image of a fiducial provided on the electronic substrate,
obtain an image of at least a portion of an object positioned on the electronic substrate,
orient the object with respect to the dispensing unit, and
perform a dispense operation to secure the object to the electronic substrate.

2. The dispensing system of claim 1, wherein the controller further is configured to manipulate the vision system with the vision gantry system to move to a position defined by a feature of the object and to acquire the image.

3. The dispensing system of claim 1, wherein performing a dispense operation includes dispensing material in the shape of an arc.

4. The dispensing system of claim 1, wherein the object is a camera having a body and a plurality of tabs extending from a periphery of the body.

5. The dispensing system of claim 4, wherein the dispensing unit is configured to dispense material between adjacent tabs.

6. The dispensing system of claim 1, wherein the controller further is configured to dispense lines of material.

7. The dispensing system of claim 1, wherein the controller further is configured to dispense dots of material.

8. The dispensing system of claim 1, wherein the dispensing unit includes a sensor configured to sense a z-axis height on the electronic substrate.

9. The dispensing system of claim 1, further comprising a support assembly coupled to the frame, the support assembly being configured to support the electronic substrate during a dispense operation.

10. A method of depositing material on an electronic substrate with a dispensing system of the type including a frame, a dispensing unit gantry movably coupled to the frame, a dispensing unit coupled to the dispensing unit gantry, the dispensing unit being configured to deposit material onto the substrate during the dispense operation, a vision system gantry coupled to the frame, and a vision system coupled to the vision system gantry, the vision system being configured to obtain one or more images of the electronic substrate prior to performing the dispense operation, the method comprising:
obtaining an image of a fiducial provided on the electronic substrate;
obtaining an image of at least a portion of an object positioned on the electronic substrate;
orienting the object with respect to the dispensing unit; and
performing a dispense operation to secure the object to the electronic substrate.

11. The method of claim 10, wherein the method is performed under the control of a controller configured to manipulate the vision system with the vision gantry system to move to a position defined by a feature of the object and to acquire the image.

12. The method of claim 11, wherein the controller further is configured to dispense lines of material.

13. The method of claim 11, wherein the controller further is configured to dispense dots of material.

14. The method of claim 10, wherein performing a dispense operation includes dispensing material in the shape of an arc.

15. The method of claim 10, wherein the object is a camera having a body and a plurality of tabs extending from a periphery of the body.

16. The method of claim 15, wherein the dispensing unit is configured to dispense material between adjacent tabs.

17. The method of claim 10, further comprising sensing a z-axis height on the electronic substrate.

18. The method of claim 10, further comprising supporting the electronic substrate during a dispense operation with a support assembly coupled to the frame.
